(19) United States
(12) Patent Application Publication
(10) Pub. No.: US 2026/0180438 A1
(43) Pub. Date: Jun. 25, 2026

(54) POWER SUPPLY MODULE AND VERTICAL POWER DELIVERY SYSTEM

(71) Applicant: MetaPWR Electronics Co., Ltd., Shanghai (CN)

(72) Inventors: Jianhong ZENG, Shanghai (CN); Shouyu HONG, Shanghai (CN); Da Jin, Shanghai (CN)

(73) Assignee: MetaPWR Electronics Co., Ltd., Shanghai (CN)

(21) Appl. No.: 19/432,139

(22) Filed: Dec. 24, 2025

(30) Foreign Application Priority Data
Dec. 24, 2024 (CN) 202411913701.4

(51) Int. Cl. H02M 3/00; H05K 1/02; H05K 1/181; H10W 40/20; H10W 40/25; H10W 40/47

(52) U.S. Cl. CPC H02M 3/003; H05K 1/0203; H05K 1/181; H10W 40/233; H10W 40/259; H10W 40/47; H05K 2201/064; H05K 2201/10015; H05K 2201/1003; H05K 2201/10212; H05K 2201/10734

(57) ABSTRACT

The present invention discloses a power supply module and a vertical power delivery system. The power supply module comprises a large-area pin board, a control module, a plurality of power blocks, a plurality of input capacitors, and a plurality of output capacitors. The controller is vertically connected to the pin board by means of a first side surface or a third side surface, so as to realize electrical connection. In the present invention, the controller is placed vertically, and as many power blocks are provided in a limited space in the power supply module, the power density or conversion efficiency of the power supply module is improved.

### CROSS-REFERENCE TO RELATED APPLICATIONS

This application claims the priority benefit of Chinese patent application 202411913701.4 filed on Dec. 24, 2024. The entirety of the above-mentioned patent application is hereby incorporated by reference herein and made a part of this specification.

### BACKGROUND

### Technical Field

The present disclosure relates to the technical field of power, and in particular to power supply module and vertical power delivery system.

### Description of Related Art

With the development of artificial intelligence, intelligent data processing chips, such as GPU/CPU/NPU/TPU, etc. (collectively, XPU) have higher and higher power requirements, and in order to reduce the losses on a printed circuit board (PCB), a vertical power delivery (VPD) structure starts to be applied, and will become the mainstream solution for powering XPU.

A power block in the vertical power delivery VPD module is the same as that of a conventional VRM, and is also a buck converter (when a input voltage is 12V, a Buck circuit is usually used; when the input voltage is higher than 12 V, there are many types of circuits, and the bridge circuit is typical), and the input voltage is reduced from a high voltage to below 1V required by the XPU. An output current of the vertical power delivery is typically up to a thousand of amperes or even thousands of amperes; although a current density is relatively large, the overall area is also relatively large. Therefore, the VPD module is large in current, large in size and large in challenge.

However, there are many problems in existing vertical power delivery structures. For example, the existing integrated VPD structure comprises a BGA (Ball Gate Alley, welded with a mainboard), an output capacitor layer, a magnetic element layer and a power semiconductor layer, etc. The layers are vertically stacked, so that the integration level of the power supply module is high and the size is large; moreover, the research and development costs are extremely high, the research and development cycle is long, and the power supply module is almost unable to repair. Moreover, since the power supply requirements of different XPU and the arrangement of the power supply pins are different, the specification of the VPD module cannot be universal, and the cost is high. Furthermore, the large-size integrated body has a complex structural stress, is difficult to match with XPU stress, brings challenges for customers to use, and affects system reliability.

Therefore, there is an urgent need for a solution for a VPD module having a large current density, being convenient for customers to use and having a low cost.

### SUMMARY

In view of the above, one of the objectives of the invention is to provide a power supply module, comprising a large-area pin board, a control module, and a plurality of power blocks;

The large-area pin board comprises a first surface and a second surface, and the first surface and the second surface are arranged opposite to each other and are used for receiving and distributing current to a computing power chip;

The power block is arranged on the first surface of the large-area pin board, and the power block is used for converting an input voltage of the power block into a low voltage;

The control module comprises at least one controller for controlling the power block;

The control module is in a cuboid shape, and comprises a top surface, a bottom surface, a first side surface, a second side surface, a third side surface and a fourth side surface, wherein the first side surface and the third side surface are arranged opposite to each other, the second side surface and the fourth side surface are arranged opposite to each other, and the area of the top surface or the area of the bottom surface is greater than the area of any side surface;

The top surface or the bottom surface of the control module is perpendicular to the first surface of the large-area pin board, and the control module is electrically connected to the large-area pin board.

Preferably, the control module is disposed in a central region of the large-area pin board; the power blocks are distributed around the control module.

Preferably, the power supply module, further comprising an input capacitor, an output capacitor, and a first symmetry axis, wherein the first symmetry axis is parallel to the top surface and/or the bottom surface of the control module, and passes through the centroid of the control module; the input capacitor and the output capacitor are arranged adjacent to the control module; the power blocks are symmetrically and evenly distributed on both sides of the first symmetry axis.

Preferably, the power blocks are symmetrically and evenly distributed around the control module by taking the centroid of the control module as a symmetric point.

Preferably, the power supply module, further comprising an input capacitor and an output capacitor;

The first surface of the large-area pin board is rectangular and comprises four corner regions;

The input capacitor and/or the output capacitor are disposed on one or more corner regions of the large-area pin board.

Preferably, the first surface of the large-area pin board is polygonal, and the polygonal shape is a rectangle cut one or more corner regions.

Preferably, the power supply module, further comprising an output capacitor;

A projection of at least half of the output capacitors on a horizontal plane of the large-area pin board falls within the large-area pin board region.

Preferably, the power block sequentially comprises an IPM or an input capacitor, a magnetic element layer and a plurality of output capacitors from top to bottom.

Preferably, the magnetic element layer includes a magnetic core; the output capacitor is first fixed to the bottom of the magnetic core in a physical manner, and then welded to the large-area pin board; the physical manner fixing comprises plastic packaging, embedding or bonding.

Preferably, the IPM includes a plurality of power semiconductors disposed adjacent to an upper surface of the IPM; the power block sequentially includes the IPM, the input capacitor, the magnetic element layer, and the plurality of output capacitors from top to bottom.

Preferably, the chip of the power semiconductor is exposed on the upper surface of the IPM, or the electroplated copper of the power semiconductor is exposed on the upper surface of the IPM.

Preferably, a ceramic plate is adhered to the other surface of the power semiconductor.

Preferably, the power block includes a multi-channel converter, and magnetic elements of the multi-channel converter are in an anti-coupling relationship or a TLVR coupling relationship.

Preferably, the power supply module, further comprising a groove, the groove being provided on the first surface of the large-area pin board; the first side surface of the control module being provided with a protrusion; the controller is inserted into the groove through the protrusion to electrically connect to the large-area pin board.

Preferably, the power supply module, further comprising an IBC and a liquid cooling plate;

The IBC is used for converting the input voltage into the input voltage of the power block;

The power block and the IBC are respectively arranged on two opposite sides of the liquid cooling plate; the liquid cooling plate is used for dissipating heat generated by the power block and the IBC.

Preferably, thermal elements in the IBC and the power block are disposed adjacent to the liquid cooling plate.

Preferably, an intermediate bus is also included; the intermediate bus is electrically connected between the IBC and the large-area pin board or between the IBC and the power block.

Preferably, the intermediate bus is electrically connected to the large-area pin board by crimping or welding.

Preferably, the intermediate bus is electrically connected to the power block by crimping or welding.

Preferably, an input terminal of the power block is disposed at a top of the power block.

Preferably, at least one side surface of the power block is provided with a shielding surface, wherein the at least one side surface is adjacent to the control module; the shielding surface is used for shielding electromagnetic interference of a magnetic element.

Preferably, the shielding surface is a large-area copper sheet for direct current power transfer, or a PCB for signal transmission.

Preferably, the control module further includes a controller substrate, a peripheral capacitor, and a peripheral resistor; the controller is a controller chip disposed in parallel with the controller substrate.

Preferably, the controller chip is remote from the side of the large-area pin board and is at least 3 mm above the first surface of the large-area pin board.

Preferably, the controller chip is directly bonded to the controller substrate, and then the controller chip electrode is guided onto the controller substrate by a wire bond process, and then the entire control module is molded.

Preferably, the control module further comprises a shielding layer, wherein the shielding layer is arranged on a top surface or a bottom surface of the controller and is used for shielding electromagnetic interference of a magnetic element.

Preferably, the power block comprises at least two output positive terminals Vout and at least two output negative terminals GND;

The output positive terminal Vout and the output negative terminal GND are evenly distributed in a contour of at least two thirds of the projection surface of the power block on the large-area pin board.

Preferably, the two output negative terminals GND are distributed near two opposite sides of the power block; the output positive terminals Vout are distributed in a relatively intermediate aliquot position.

Preferably, the output negative terminal GND and the output positive terminal Vout are balanced and staggered relative to each other.

Preferably, wherein each power block comprises at least four power units;

The output positive terminal Vout of each power unit is connected in parallel on the large-area pin board;

An output capacitor is disposed in the blank area between the output positive terminal Vout and the output negative terminal GND pin.

Preferably, at least four power units operate at the same frequency, and have an equalization staggered phase and a total phase of 360 degrees.

Preferably, the magnetic element includes an inductive winding; the inductive winding penetrates from above the magnetic element in a single turn and in a straight line manner.

Preferably, a plurality of test points are further arranged on the first side surface or the third side surface of the control module, and the test points are arranged in an array.

Preferably, an input power electrodes Vin and GND of the input terminal are disposed on a top electroplated layer of the power block.

A vertical power delivery system, comprising:
Comprising a computing power chip, a system PCB, and the power supply module;
The computing power chip and the power supply module are respectively arranged on two sides of the system PCB;
The computing power chip, the system PCB, and the power supply module are electrically connected.

Preferably, the large-area pin board is integrated on the surface layer of the system PCB.

Compared with the prior art, the application has the following beneficial effects:

According to the present application, the controller is placed vertically, and as many power blocks are provided in the limited space of the power supply module, the power density or conversion efficiency of the power supply module is improved.

The test points are disposed on the first side surface or the third side surface of the controller to facilitate testing.

In the present application, the capacitors are first fixed below the magnetic element layer, and then welded to the large-area pin board, thereby greatly reducing the possibility of occurrence of tombstoning, component drifting, or even insufficient soldering.

In the present application, most of the input capacitor, the magnetic element, and the output capacitor are integrated into the IPM, thereby reducing the occupation of the bottom space of the power block.

The IPM is disposed at the top of the power block to facilitate heat dissipation.

The present application is electrically connected to the controller and the large-area pin board by means of SMD Socket, so that the power supply module can flexibly adapt to different scenarios.

The power block uses the multi-channel converter, and the magnetic elements between the multi-channel converter is in an anti-coupling or TLVR coupling relationship, so that the dynamic inductance is much smaller than the steady-state inductance, and the demand for the number of capacitors is reduced.

According to the present application, the input power electrodes Vin and GND are arranged on the top electroplated layer of the power block, so that the occupation of pin resources at the bottom of the module and the occupation of surface resources of the large-area pin board and the pin occupation of the large-area pin board are greatly reduced, and the power density of the power supply module is further improved.

According to the present application, the TLVR is guided to the top electroplated circuit layer of the module, and is interconnected by means of a crimping technology, thereby reducing the resource occupation of the large-area pin board.

### BRIEF DESCRIPTION OF THE DRAWINGS

FIG. 1A is a schematic diagram of a vertical power delivery system in the prior art.

FIG. 1B is a top view of a power supply module.

FIG. 1C is a cross-sectional view of a power supply module.

FIG. 2A is a schematic diagram of a vertical power delivery system according to an embodiment.

FIG. 2B is a top view of a power supply module according to an embodiment.

FIG. 3 is a schematic cross-sectional view of a power supply module according to an embodiment.

FIG. 4A is a schematic cross-sectional view of another power supply module according to an embodiment.

FIG. 4B is a top view of another power supply module of the present embodiment.

FIG. 5A is a schematic diagram of capacitance distribution in a power supply module.

FIG. 5B is a schematic diagram of another capacitance distribution in the power supply module.

FIG. 6A is a schematic structural diagram of a two-stage conversion of a power supply module.

FIG. 6B is another schematic structural diagram of two-stage conversion of a power supply module.

FIG. 7 is a schematic diagram of distribution of shielding surfaces of a power supply module.

FIG. 8 is a schematic diagram of an internal structure of a controller.

FIG. 9 is a schematic diagram of pin distribution on the large-area pin board.

### DESCRIPTION OF THE EMBODIMENTS

Technical solutions in the embodiments of the present disclosure will be clearly and completely described below with reference to the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

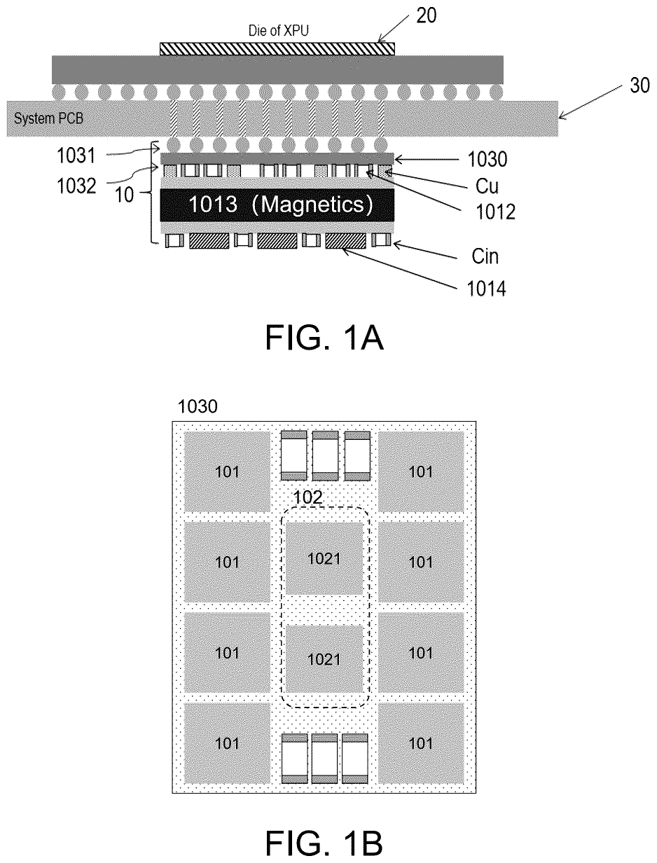

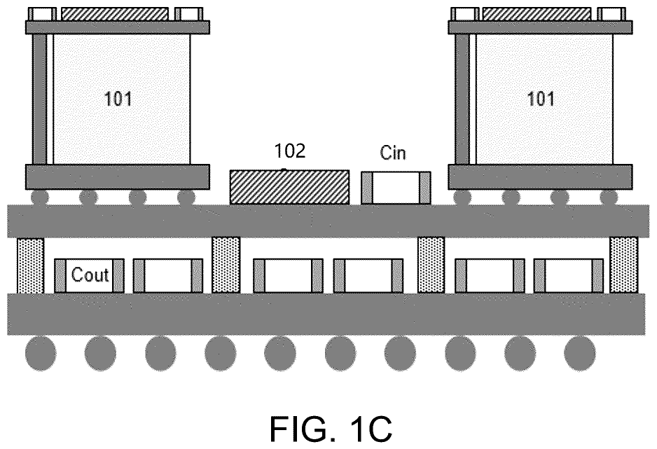

FIG. 1A is a schematic diagram of a vertical power delivery system in the prior art; FIG. 1B is a schematic diagram of an internal structure of a power supply module 10; and FIG. 1C is a cross-sectional view of a power supply module 10. The structure of the existing vertical power delivery system is as shown in FIG. 1A, and the computing power chip (XPU) 20 and the power supply module 10 are respectively arranged on two sides of the system board 30. The power supply module 10 generally comprises a large-area pin board 1030, an output capacitor layer 1012, a magnetic element layer 1013, and a power semiconductor layer 1014. The large-area pin board 1030 comprises a first surface 1031 and a second surface 1032 opposite to each other; a BGA used for welding with the main board is arranged on the first surface 1031; the output capacitor layer 1012 is arranged on the large-area pin board 1030 of the second surface 1032; the output capacitor layer 1012, the magnetic element layer 1013 and the power semiconductor layer 1014 are stacked in the vertical direction, and these devices are integrated as a whole. Since the power density is high, and the space must be utilized meticulously to achieve maximum efficiency, the research and development costs of such a large-size integrated body is very high, the research and development cycle is long, and it is almost impossible to repair. In addition, since the power supply requirement of each XPU is different, even the pin arrangement for the power supply module 10 is different, the power supply module 10 supplied to each XPU has different specifications, which cannot be universal, and the research and development costs remain extremely high. Moreover, such a large-sized integrated body has a complex structural stress, and is difficult to match with XPU stress, resulting in increased customer usage difficulty and affecting the reliability of a vertical power delivery system.

As shown in FIGS. 1B and 1C, the prior art power supply module 10 includes a plurality of small current power blocks 101, the large-area pin board 1030, and a control module 102. The power block 101 herein is a standard member, so that the power block 101 can be optimized and reused to achieve the effect of shortened development cycle and flexible configuration. However, the power block 101 is not a dedicated design of the power supply module 10. Therefore, the complex structure of the power supply module 10 affects its reliability and a low space utilization rate impacts the performance of the module.

As shown in FIG. 1B, the control module 102 includes a plurality of controllers 1021 (overall in the shape of a cuboid), and each controller 1021 is substantially in the shape of a cuboid, and the horizontal cross-section is greater than the other direction cross-section. The controller 1021 disposed on the large-area pin board 1030 in a horizontal cross-section, i.e. in contact with the large-area pin board 1030 with a maximum area of cross-section, greatly wasting the surface space of the large-area pin board 1030.

In view of this, this embodiment provides a solution for a power supply module 10 with a large current density, a low cost, and a flexible configuration, and a corresponding vertical power delivery system.

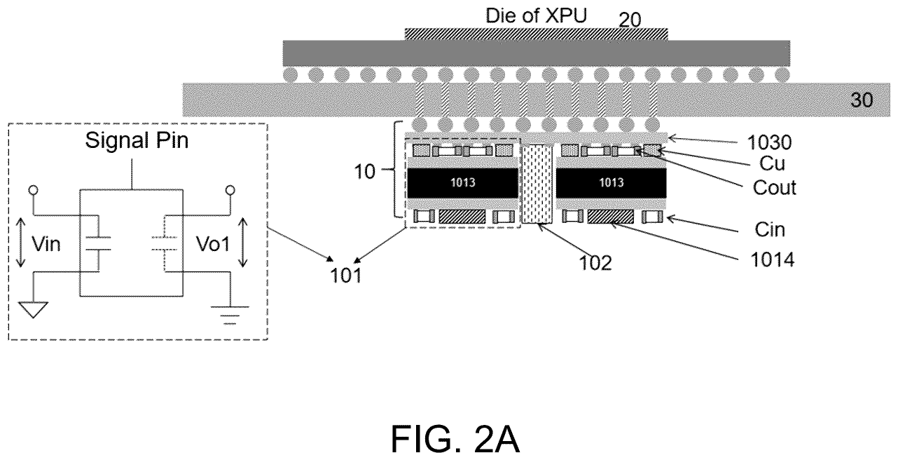

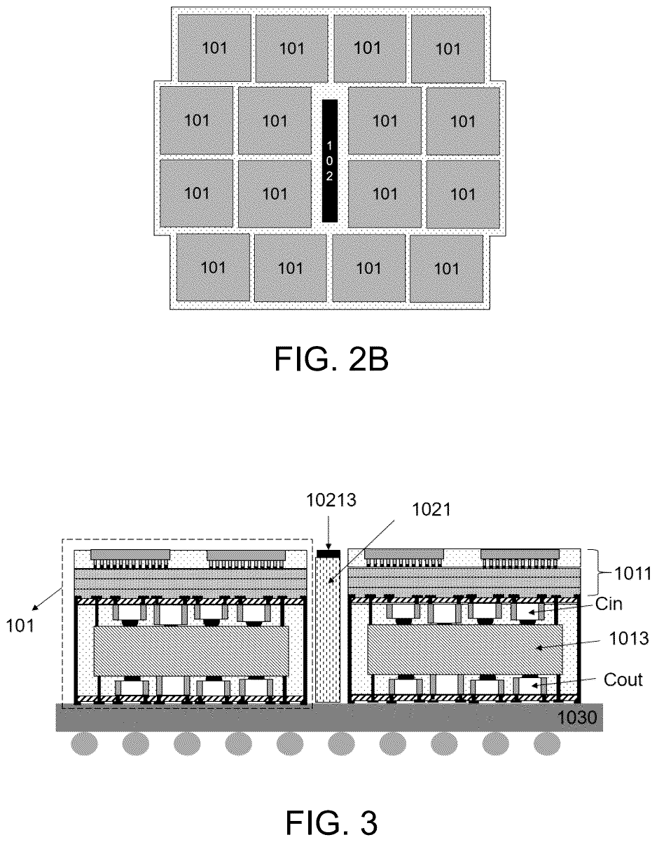

FIG. 2A is a schematic diagram of a vertical power delivery system according to an embodiment; and FIG. 2B is a top view of a power supply module 10 of the present embodiment. As shown in FIG. 2A and FIG. 2B, the power supply module 10 in this embodiment includes only one large-area pin board 1030 (large board for short), and the large-area pin board 1030 serves as a pin board of the power supply module 10 for receiving and distributing current to the computing power chip 20.

The large-area pin board 1030 comprises a first surface 1031, a second surface 1032 and four sides. The first surface 1031 and the second surface 1032 are opposite and each has a larger area. The first surface 1031 is implanted with a BGA for welding, or is provided with a pad for crimping; and the BGA or the pad is used for directly or indirectly transferring a large current output by the power supply module 10 to the computing power chip (Die of XPU).

The second surface 1032 is directly or indirectly provided with a plurality of power blocks 101, each power block 101 may convert an input high voltage to a low voltage in an isolated or non-isolated form. The power block 101 typically comprises a power semiconductor 1014; wherein the plurality of power blocks 101 may each accept a control signal. The control signal originates from one or more controllers integrated in the power supply module 10, enabling the power supply module to provide one or more output steady-state and dynamic supply of energy capability according to the system requirements. The projection of the power block 101 on the horizontal plane where the large-area pin board 1030 is located falls within the region of the large-area pin board 1030, and the projection of the most high-frequency input capacitor Cin and the high-frequency output capacitor Cout (>50%, especially >75%) needed to be built into on the horizontal plane of the large-area pin board 1030 falls within the region of the large-area pin board 1030. The magnetic element may be a transformer or an inductor.

It should be noted that, in some special applications, when the power supply module 10 does not require a built-in output capacitor Cout, it can still be considered that the most output capacitor Cout is located in the projection region of the power supply modules 10; and the output capacitor Cout can be embedded in the pin board or is disposed in the two large-board interlayers, as long as it can be projected in the power block 101.

In the present embodiment, the controller 1021 is erected on the large-area pin board 1030. Compared with the traditional flat spreading on the large-area pin board 1030, the height of the power supply module 10 can be fully utilized, so that the control circuit occupies as few as possible the area on the second surface 1032 of the PCB, and as much space as possible is set as many power blocks 101 as possible, thereby improving the power density or conversion efficiency of the power supply module.

In the present embodiment, and there is only one large-area pin board 1030, the power supply module 10 may provide as much height as possible to the power block 101.

In summary, the power block 101 of the present embodiment obtains a maximum area and a maximum height, so as to obtain more optimization opportunities, and can achieve the optimal performance of the power supply module 10. In this way, the power block 101 and the control module 102 in the power supply module 10 of the present embodiment are each defined based on the overall optimization of the power supply module, which not only perfectly uses the space in the power supply module 10, but also realizes flexible configuration according to different XPU requirements.

In terms of performance, in an application scenario where the total height of the power supply module 10 is 7 mm, as shown in FIG. 1C, the height of the power block 101 is less than 4 mm to satisfy the total height of 7 mm. In this embodiment, the height of the power block 101 is 5.5 mm, which is 37.5% higher than the height in the prior art. In addition, in the prior art, the horizontal cross-sectional area of the power block 101 is 9*10 mm², and the horizontal cross-sectional area of the power block 101 in the present embodiment is 11*11 mm²; compared with the prior art, the horizontal cross-sectional area of the power block 101 is increased by 34.4%, and the volume of the power block 101 is increased by 85%. Therefore, compared with the prior art, the power density of the power supply module 10 of the present embodiment is increased by 85%, and can meet the requirements of at least two generations of computing power chips XPU.

In terms of flexibility, the power density of the power block 101 of the present embodiment is higher, and the same number of power blocks 101 can be configured with more XPUs. The power supply module 10 of the present embodiment can meet the requirements of different XPUs only by means of wiring and manufacturing different large-area pin boards 1030, and the development cycle of the power supply module can be shortened from traditional 1.5 years to 0.5 years, and the development cycle and cost are greatly reduced. However, since the power block 101 of the present embodiment has good universality, the cost of the power block 101 can be further reduced.

Therefore, the power supply module 10 provided in this embodiment has greatly improved the complex manufacturing process, high cost, long production cycles and poor performance in the prior art.

In addition, in this embodiment, the large-area pin board 1030, the power block 101, and the control module 102 are decoupled, that is, the three can be independently arranged, and the three can be respectively optimized, so that the overall value of the power supply module can be improved, and the local mutual promotion and common iteration can be achieved; in addition, the control module 102 occupies a smaller area, so that the power supply module 10 has a larger area to configure the power blocks 101. In addition, the large area pin board 1030 in the present embodiment becomes thinner, such that the power block 101 has a higher height. Further, the power block 101 can be continuously optimized in terms of frequency, dynamic performance, and power density, so that the power supply module 10 of the present embodiment has better product competitiveness.

Furthermore, as shown in FIG. 2B, the arrangement of the inner part of the power supply module 10 is very compact, which can lead to the difficulty of debugging and repairing or even factory testing, affecting the working efficiency and product quality of production. According to the power supply module 10 shown in FIG. 3, the height of the control module 102 is cleverly utilized, and on the top of the vertically placed controller 1021, the test points 10213 are arranged in an array, which not only saves space, but also facilitates the operator to test the power supply module 10.

Furthermore, as shown in FIG. 2A, the output capacitor Cout is arranged at the bottom of the power block 101, and is welded to the large-area pin board 1030 together with the power block 101. Then, the welding quality of the output capacitor Cout is difficult to control and difficult to detect. Since the output capacitor Cout of the entire power supply module 10 is up to thousands, if there is one soldering defect (such as tombstoning, component drifting, or even insufficient soldering), the poor performance of the whole power supply module 10 is obtained, and the manufacturing yield of the module is affected. In the embodiment shown in FIG. 3, the output capacitor Cout is fixed in the bottom of the magnetic element layer 1013 in the power block 101 by means of physical means (such as by plastic encapsulation, embedding, bonding, etc.), and the flatness of the pads of these capacitors and the other pads of the power block 101 is controlled to be within 100 μm. In this way, many output capacitors and power blocks 101 can be combined into one component, and then welded to the large-area pin board 1030, thereby greatly reducing the possibility of tombstoning, component drifting, or even insufficient soldering.

Furthermore, the conventional power supply module 10 is provided with a large number of input capacitors Cin at the bottom of the power block 101, and the input capacitor occupies a large amount of space of the module and planar resources of the large-area pin board 1030. As shown in FIG. 3, the structure of the power block 101 of the present embodiment is from top to bottom: an IPM (Intelligent Power Module) 1011, a majority of input capacitors Cin, a magnetic element layer 1013, and an output capacitor Cout, wherein the IPM 1011 comprises an integrated power semiconductor and a driver thereof, the at least two semiconductor chips are directly integrated in one package body, the thickness of the chip is thinner than 0.4 mm, and the thickness of the entire IPM 1011 is thinner than 1.0 mm. Most (excess of 50% or even 75%) of the input capacitors Cin are built in the power supply. In this way, the number of input capacitors at the bottom of the power block 101 is reduced, enough space is released to the output capacitor Cout, more output capacitors Cout can be arranged at the bottom of the power block 101, and the resources of the large-area pin board 1030 are also released, so that the number of layers of the large-area pin board 1030 is reduced, and the power block 101 can be further provided with a higher height.

Furthermore, as shown in FIG. 3, due to the power density of the power supply module 10 of the present disclosure is higher, the thermal density of the module is usually increased accordingly, and therefore, the module needs a better heat dissipation channel. In this embodiment, the power semiconductor is arranged at the top of the power block 101. For better heat dissipation, the power semiconductor chip is directly exposed in the present implementation, or the electroplated copper of the power semiconductor chip is exposed, or the power semiconductor takes a thermally good conductor with a thermal conductivity higher than 10 K/m*W, or a heat-dissipating ceramic plate is disposed on the power semiconductor.

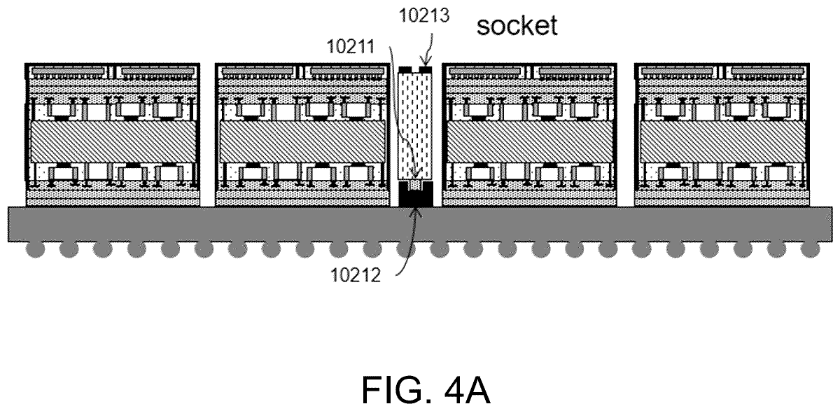

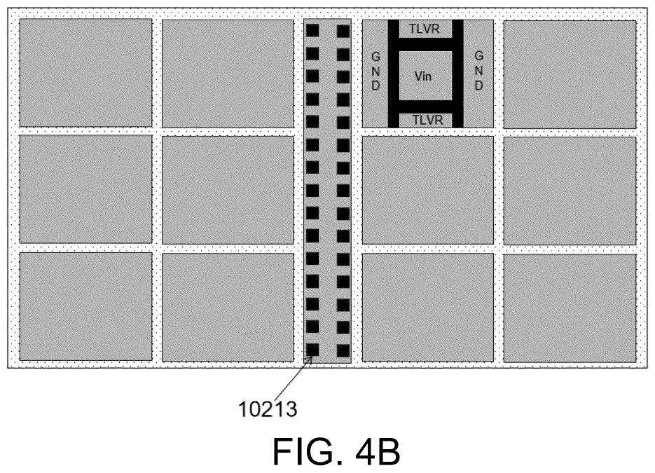

Furthermore, as shown in FIG. 4A, the erected controller 1021 is arranged in an SMD socket, that is, the controller 1021 is electrically connected to the large-area pin board 1030 by means of the insertion of the protrusion 10211 and the groove 10212.

The present implementation uses SMD Socket to only weld a socket for an interconnection with the control module, thereby reducing the manufacturing difficulty of the module, and also providing the advantage of flexible configuration of the control module 102. The control upgrade of the traditional power supply module 10 can only be implemented by software upgrade, and the present invention can implement hardware upgrade only by replacing a control module hardware. Moreover, for scenarios in which different controller requirements are required, only the power stage of the power supply module 10 is produced, and different control modules are configured to achieve the flexibility selection of different applications. In addition, the control module 102 support individual program burned in, and the power supply module 10 does not need to provide burn-in pins, thereby reducing the resource occupation of wiring layer resources and pins of the large-area pin board 1030.

Furthermore, since the power density of the power supply module 10 is extremely high, even more space is reserved for the output capacitor Cout as much as possible, the capacitance of the output capacitor is also insufficient. Therefore, as shown in FIG. 4B, the power block 101 of the present embodiment adopts a multi-channel converter (2, 4, or even more), and the magnetic element of the multi-channel converter is an anti-coupling or TLVR coupling relationship, so that the dynamic inductance is much smaller than the steady-state inductance (which is much smaller than it can be defined as: ½ or less), so as to reduce the requirement of the module on the output capacitor Cout.

Furthermore, as shown in FIG. 4B, in the present invention, the input power electrodes Vin and GND are arranged on the top electroplated layer of the power block 101, which greatly reduces the occupation of pin resources at the bottom of the power supply module 10 and the occupation of pin resources on the large-area pin board 1030, and further improves the power density of the power supply module 10.

Furthermore, when the input power electrode Vin is disposed on the top of the power block 101, the input voltage should exceed more than 20 times the output voltage, such as a 48V system voltage, thereby reducing the area requirement of the input pin.

Furthermore, since the input power electrode Vin is more easily isolated on the top of the power block 101, the input terminal and the output terminal can be more easily isolated, the input voltage can exceed 60V or even up to 400 V and above, and can be isolated by using a safety isolation conversion circuit.

Furthermore, the TLVR windings of the multi-channel magnetic element need to be connected in series when using the TLVR. The bottom of the power blocks 101 are connected in series by means of a large-area pin board 1030 in traditional technology, which not only occupies the surface resources of the large-area pin board 1030, but also needs to increase the number of wiring layers of the large-area pin board 1030, and the number of output capacitors Cout is limited. As shown in FIG. 4B, in this embodiment, the TLVR pin is guided to the top electroplated circuit layer of the module, and is interconnected by means of a crimping technology, thereby reducing the occupation of surface resources of the large-area pin board 1030.

Furthermore, when the input power electrode is provided on the top of the power block 101, in such a high power density scenario, it is difficult to achieve synchronous optimization of electrical transmission and heat dissipation processing. In this embodiment, the power semiconductor is arranged on the side surface of the power block 101 and is dissipated by immersion cooling. As such, all surfaces of the power block 101 function as heat transfer or power transfer and can each be optimized.

Furthermore, the structure disclosed in the present embodiment is more suitable for an application scenario in which the number of power blocks 101 exceeds four, such that the distance between the control module and each power block 101 is similar, and the control module 102 is provided in a central region of the large-area pin board 1030 of the power supply module 10, wherein the contact surface between the control module 102 and the large-area pin board 1030 is an elongated rectangle, and the control module 102 is vertically arranged on the second surface 1032 of the large-area pin board 1030, so as to occupy as little as possible the surface resources of the large-area pin board 1030 and facilitate arrangement.

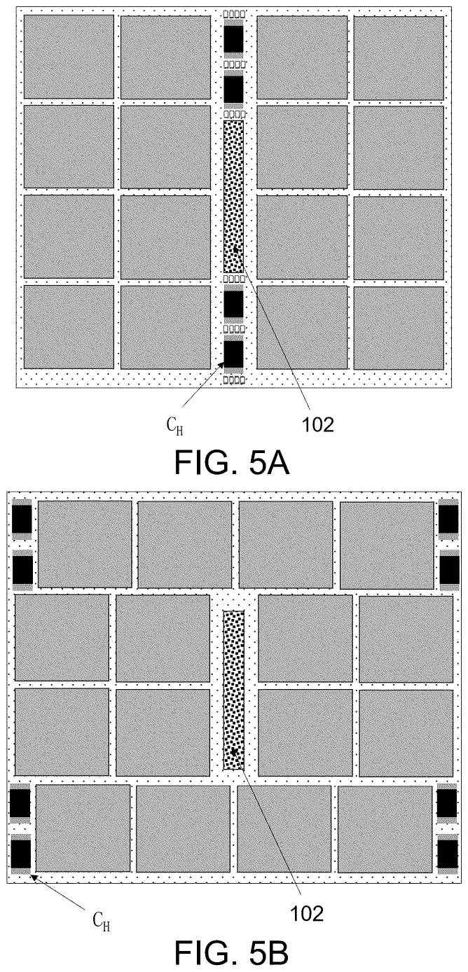

Furthermore, as shown in FIG. 5A, all power blocks 101 are provided on the left and right sides of the control module. The output capacitor Cout or the input capacitor Cin can be arranged above and/or below the control module 102, and in particular, a high-capacity capacitor and a high-frequency capacitor (collectively referred to as CH) can be set up, so as to realize the balance of high-frequency impedance and space utilization of the output pin of the power supply module 10.

Furthermore, as shown in FIG. 5B, the power blocks 101 are placed around the control module 102. The top view of the power supply module 10 is still a regular square. Then, at least one of the four corners of the power supply module 10 may be provided with the output capacitor Cout or the input capacitor Cin, and in particular, the high-capacity capacitor and the high-frequency capacitor may be mixed.

Further, referring again to FIG. 2B, the power blocks 101 are placed around the control module 102. At least one of the four corners of the large-area pin board 1030 is removed to leave space to the system board to facilitate customer use.

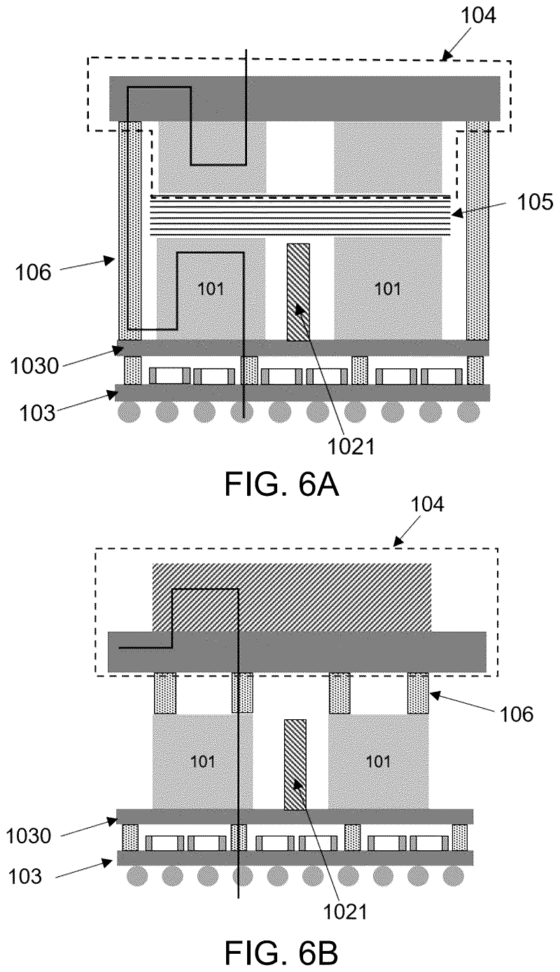

Furthermore, as shown in FIGS. 6A and 6B, the power supply module 10 is a two-stage conversion architecture, a first stage is an intermediate bus converter IBC 104; the IBC 104 receives the input voltage, and converts into a voltage of the intermediate bus 106; a second stage is the power block 101, and the power block 101 converts the voltage of the intermediate bus 106 into the output voltage. In this embodiment, IBC 104 is stacked above the power block 101.

As shown in FIG. 6A, the IBC 104 and the power block 101 are respectively arranged on two opposite sides of the liquid cooling plate 105, a thermal element of the IBC 104 is centrally arranged below the IBC 104, the thermal element of the power block 101 is concentrated above the power block 101, and the two thermal elements share one liquid cooling plate 105; that is, the stacked structure is from top to bottom: the IBC 104, the liquid cooling plate 105, and the power block 101. The output of the IBC 104, i.e. the intermediate bus 106, is crimped or welded to the large-area pin board 1030 on which the power block 101 is mounted by means of the connector, so that the high-density integration is realized, and the heat dissipation is convenient.

FIG. 6B shows another embodiment of a two-stage architecture. The output of the IBC 104 is that the intermediate bus 106 is crimped or welded to the top of the power block 101 by means of the connector. The input terminal in the power block 101 is provided at the top of the power block 101, which not only reduces the resource occupation of the large-area pin board 1030, but also shortens the power transmission path. In the embodiments shown in FIG. 6A and FIG. 6B, a pin board 103 is further included for carrying more output capacitors Cout and a fixed electrical connection with an external system board.

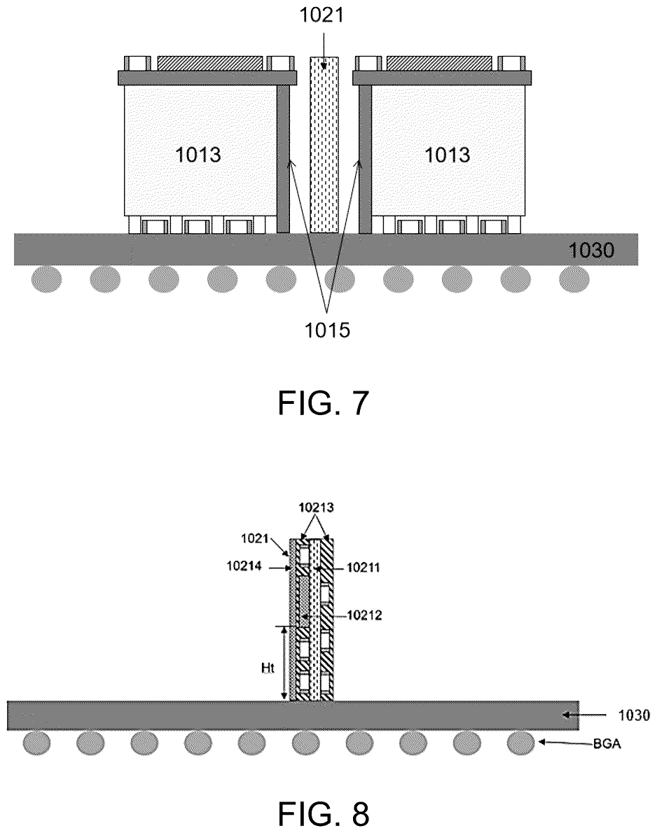

Furthermore, since the controller 1021 is erected installation, the weak-signal component and the electrical loop on the controller 1021 are relatively close to the built-in magnetic element of the power block 101 and have a large coupling area, and electromagnetic interference is prone to occur, affecting the normal operation of the module, thereby affecting the reliability of the module. In order to solve this problem, the present invention proposes an embodiment as shown in FIG. 7, at least one side surface of the power block 101 is provided with a printed circuit board for signal transmission, or a large-area copper sheet (the copper sheet can also be implemented on the printed circuit board) for direct current power transfer, thereby constituting a shielding surface 1015, and the shielding surface 1015 can shield the electromagnetic interference of the magnetic element. Preferably, the shielding surface 1015 is parallel to the controller 1021 and is arranged towards the controller 1021.

Furthermore, as shown in FIG. 8, the controller 1021 includes an erected substrate 10211, a controller chip 10212 disposed in parallel with the substrate, and necessary peripheral capacitors and resistors. The controller chip 10212 is disposed on the controller 1021 away from the side of the large-area pin board, and the shortest distance Ht from the controller chip 10212 to the upper surface of the large-area pin board 1030 is at least 3 mm, thereby achieving an optimal effect of erecting.

Furthermore, the controller chip 10212 is directly bonded to the substrate 10211, and each electrode is guided onto the substrate 10211 by means of a wire bond process, so as to satisfy the application of a limited height of the controller 1021, and then the two opposite sides and the device or the one side and the device are molded to form a plastic encapsulation layer 10213.

Furthermore, the controller chip 10212 is pre-packaged into a plastic package having a short side that is narrower than 5.5 mm or even 5 mm, the plastic package having a BGA array or LGA array to meet the application of a limited height of the controller 1021.

Furthermore, in order to make the setting of the power block 101 more flexible, a shielding layer 10214 can be arranged on the controller 1021. Preferably, when the pre-packaged controller chip is used, the shielding layer 10214 is a metal cover; and when the integrally packaged controller 1021 is used, shielding can be performed by means of the plastic packaging body surface coating.

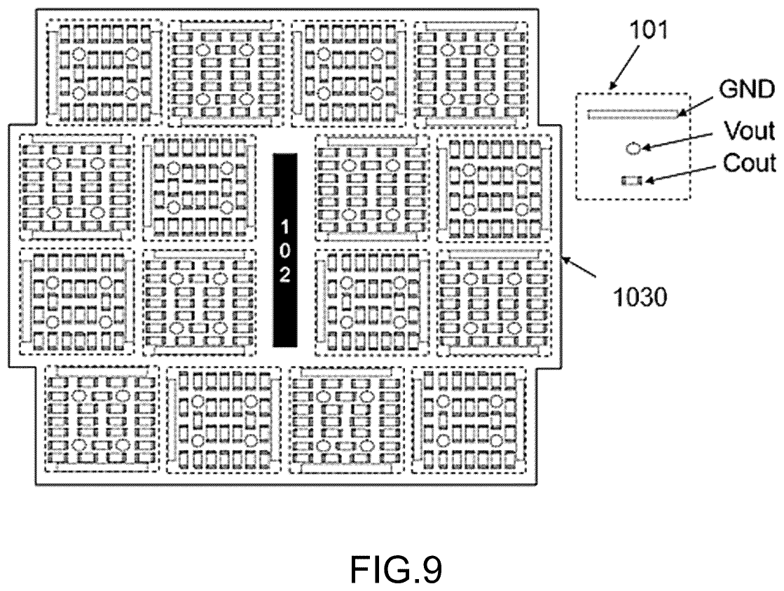

Furthermore, as shown in FIG. 9, since the current density of the power supply module 10 provided in this embodiment is large, the current flowing through the output power pin Vout and GND of the power block 101 is large, so as to shorten the distance from the output power pin to each solder ball on the large-area pin board 1030 as much as possible, so as to reduce the number and thickness of wiring layers of the large-area pin board 1030, and the electrodes of the output negative terminal GND and the output positive terminal Vout of each power block 101 are relatively uniformly arranged in a contour of at least two thirds of the bottom surface of the power block 101.

Furthermore, the numbers of the output negative terminal GND and the output positive terminal Vout are at least one pair, and the two output negative terminals GND are distributed near two opposite sides of the power block 101, and the output positive terminal Vout is distributed at a relatively middle equal division position.

Furthermore, the output negative terminals GND of two adjacent power blocks 101 are staggered by 90 degrees, so as to realize when the plurality of power blocks 101 are arranged, the output negative terminal GND and the output positive terminal Vout under the total contour are relatively balanced and staggered, so that most of the output negative terminal pins and the output positive terminal pins on the large-area pin board 1030 can obtain a current supply at a distance shorter than two-thirds or even one-half of the width of the power block 101, and the transverse current path is shorter, thereby reducing the resource dependence on the printed circuit board, and making the thickness of the large-area pin board 1030 thinner.

Furthermore, each power block 101 integrates at least four power units, and the current output channels Vout of the respective power units are connected in parallel on the large board. In addition, each power unit is evenly distributed in the projection region of the power block 101, and a blank region between each output positive terminal Vout and the output negative terminal GND pin can be used to set the output capacitor Cout. Therefore, the output capacitor Cout is very close to both the output positive terminal Vout and the output negative terminal GND, which reduces the need for lateral current transfer and reduces the thickness of the large-area pin board 1030.

Furthermore, at least four power units integrated by each power block 101 are in the same frequency, and are interleaving phase balancing, that is, if it is a 4-phase power unit, the phase difference between adjacent power units is 360/4 degrees (=90 degrees), and the cancellation of the output current ripple is realized by means of the arrangement of the staggered phase, thereby reducing the demand for the capacity of the output capacitor Cout.

Furthermore, in a power block integrating at least four interleaved phases, an anti-coupling or TLVR design is used for the magnetic element, thereby further greatly reducing the demand for the output capacitor Cout, or greatly increasing the amount of current that can be supported by the capacitance of the unit output capacitor.

Furthermore, since the current density of the power block 101 integrated in the power supply module 10 is large, when the conversion circuit is buck, and the power block 101 structure is that the power semiconductor is arranged on the inductor, in order to reduce the losses of the inductor winding, the inductor winding penetrates the inductor from above the inductor in a single turn and in a straight line manner, so as to achieve the shortest distance of the power transmission power; and the output capacitor Cout is arranged at the bottom of the inductor, and is arranged between the output negative terminal GND and the output positive terminal Vout, and is respectively welded on the large board, thereby achieving the purpose of reducing the thickness of the large board. The module structure and the technical features disclosed in the present invention are not only applicable to the VPD module, but also can be applied to other power supply modules with high density requirements, and can also reduce the horizontal size of the power supply module and improve the power density of the power supply module.

Furthermore, when the conversion circuit is buck, and the power block 101 structure is the inductor disposed on the power semiconductor, the output capacitor Cout is disposed using a single-printed circuit board embedded process or a dual-printed circuit board interlayer, so as to realize large-area placement of the output capacitor Cout.

Since a plurality of embodiments of the present invention are single or superimposed on each other, a very thin large board can be used, and the thickness thereof is even thinner than 0.8 mm from an electrical demand, such that most of the space of the power supply module 10 is used to set a power block 101; however, such a thin large board, when the horizontal cross-sectional area of the power supply module 10 is greater than 25 square centimeters, warpage deformation easily occurs during the manufacturing process, resulting in difficulty in customer use. The traditional power supply module 10 can perform flatness consolidation by providing coarse and wide steel bars, screws, etc., but this obviously violates the requirement of high power density, which affects the use of space. The present invention proposes a flatness consolidation mode having a small footprint and strong rigidity. According to the fixing method, a narrow and high gap between two modules is fully utilized, a grid-shaped high-strength frame is used; high-temperature glue bonding or ultrasonic welding is used; the frame is fixed on the large board, and the frame is forcibly leveled, so that the power supply remains flat during production and use. In a closer step, the framework can be removed after a customer completes application welding, and is merely used as a production process.

The “equal” or “same” or “equal to” disclosed in the present invention all must consider the parameter distribution of an engineering, and the error distribution is within +30%; two line segments or two straight lines “parallel” are defined as the included angles between the two line segments or the two straight lines being less than or equal to 45 degrees; the two line segments or the two straight lines “vertical” define the included angles of the two line segments or the two straight lines in the [60, 120] degree range; the definition of the phase “error phase” also needs to consider the parameter distribution of the engineering, and the error distribution of the error phase degree is within +30%. In addition, relational terms, such as first and second, etc. are used herein merely to distinguish one entity or operation from another without necessarily requiring or implying any such actual relationship or order between such entities or operations. Moreover, the terms “comprise”, “comprise” or any other variation thereof are intended to cover a non-exclusive inclusion, such that a process, method, article, or device that includes a list of elements not only includes those elements, but also includes other elements not expressly listed, or further includes elements inherent to such a process, method, article, or device. Without more restrictions, the statement “comprising one defined element”, which does not exclude the existence of additional identical elements in the process, method, article, or device that includes the element.

The embodiments in the specification are described in a progressive manner, each embodiment focuses on the difference from other embodiments, and the same similar parts between the embodiments can be referred to each other.

The above description of the disclosed embodiments enables a person skilled in the art to implement or use the present application. Various modifications to these embodiments will be readily apparent to those skilled in the art, and the generic principles defined herein may be implemented in other embodiments without departing from the spirit or scope of the application. Thus, the present application will not be limited to the embodiments shown herein but is to be accorded the widest scope consistent with the principles and novel features disclosed herein.

What is claimed is:

1. A power supply module, comprising a large-area pin board, a control module, and a plurality of power blocks;
the large-area pin board comprises a first surface and a second surface, and the first surface and the second surface are arranged opposite to each other and are used for receiving and distributing current to a computing power chip;
the power block is arranged on the first surface of the large-area pin board, and the power block is used for converting an input voltage of the power block into a low voltage;
the control module comprises at least one controller for controlling the power block;
the control module is in a cuboid shape, and comprises a top surface, a bottom surface, a first side surface, a second side surface, a third side surface and a fourth side surface, wherein the first side surface and the third side surface are arranged opposite to each other, the second side surface and the fourth side surface are arranged opposite to each other, and the area of the top surface or the area of the bottom surface is greater than the area of any side surface;
the top surface or the bottom surface of the control module is perpendicular to the first surface of the large-area pin board, and the control module is electrically connected to the large-area pin board.

2. The power supply module of claim 1, wherein the control module is disposed in a central region of the large-area pin board; the power blocks are distributed around the control module.

3. The power supply module of claim 2, further comprising an input capacitor, an output capacitor, and a first symmetry axis, wherein the first symmetry axis is parallel to the top surface and/or the bottom surface of the control module, and passes through the centroid of the control module; the input capacitor and the output capacitor are arranged adjacent to the control module; the power blocks are symmetrically and evenly distributed on both sides of the first symmetry axis.

4. The power supply module of claim 2, wherein the power blocks are symmetrically and evenly distributed around the control module by taking the centroid of the control module as a symmetric point.

5. The power supply module of claim 4, further comprising an input capacitor and an output capacitor;
the first surface of the large-area pin board is rectangular and comprises four corner regions;
the input capacitor and/or the output capacitor are disposed on one or more corner regions of the large-area pin board.

6. The power supply module of claim 4, wherein the first surface of the large-area pin board is polygonal, and the polygonal shape is a rectangle cut one or more corner regions.

7. The power supply module of claim 1, further comprising an output capacitor;
a projection of at least half of the output capacitors on a horizontal plane of the large-area pin board falls within the large-area pin board region.

8. The power supply module of claim 1, wherein the power block sequentially comprises an IPM or an input capacitor, a magnetic element layer and a plurality of output capacitors from top to bottom.

9. The power supply module of claim 8, wherein the magnetic element layer includes a magnetic core; the output capacitor is first fixed to the bottom of the magnetic core in a physical manner, and then welded to the large-area pin board; the physical manner fixing comprises plastic packaging, embedding or bonding.

10. The power supply module of claim 8, wherein the IPM includes a plurality of power semiconductors disposed adjacent to an upper surface of the IPM; the power block sequentially includes the IPM, the input capacitor, the magnetic element layer, and the plurality of output capacitors from top to bottom.

11. The power supply module of claim 10, wherein the chip of the power semiconductor is exposed on the upper surface of the IPM, or the electroplated copper of the power semiconductor is exposed on the upper surface of the IPM.

12. The power supply module of claim 10, wherein a ceramic plate is adhered to the other surface of the power semiconductor.

13. The power supply module of claim 8, wherein the power block includes a multi-channel converter, and magnetic elements of the multi-channel converter are in an anti-coupling relationship or a TLVR coupling relationship.

14. The power supply module of claim 1, further comprising a groove, the groove being provided on the first surface of the large-area pin board; the first side surface of the control module being provided with a protrusion; the controller is inserted into the groove through the protrusion to electrically connect to the large-area pin board.

15. The power supply module of claim 1, further comprising an IBC and a liquid cooling plate;
the IBC is used for converting the input voltage into the input voltage of the power block;
the power block and the IBC are respectively arranged on two opposite sides of the liquid cooling plate; the liquid cooling plate is used for dissipating heat generated by the power block and the IBC.

16. The power supply module of claim 15, wherein thermal elements in the IBC and the power block are disposed adjacent to the liquid cooling plate.

17. The power supply module of claim 15, wherein an intermediate bus is also included; the intermediate bus is electrically connected between the IBC and the large-area pin board or between the IBC and the power block.

18. The power supply module of claim 17, wherein the intermediate bus is electrically connected to the large-area pin board by crimping or welding.

19. The power supply module of claim 17, wherein the intermediate bus is electrically connected to the power block by crimping or welding.

20. The power supply module of claim 1, wherein an input terminal of the power block is disposed at a top of the power block.

21. The power supply module of claim 1, wherein at least one side surface of the power block is provided with a shielding surface, wherein the at least one side surface is adjacent to the control module; the shielding surface is used for shielding electromagnetic interference of a magnetic element.

22. The power supply module of claim 21, wherein the shielding surface is a large-area copper sheet for direct current power transfer, or a PCB for signal transmission.

23. The power supply module of claim 1, wherein the control module further includes a controller substrate, a peripheral capacitor, and a peripheral resistor; the controller is a controller chip disposed in parallel with the controller substrate.

24. The power supply module of claim 23, wherein the controller chip is remote from the side of the large-area pin board and is at least 3 mm above the first surface of the large-area pin board.

25. The power supply module of claim 23, wherein the controller chip is directly bonded to the controller substrate, and then the controller chip electrode is guided onto the controller substrate by a wire bond process, and then the entire control module is molded.

26. The power supply module of claim 23, wherein the control module further comprises a shielding layer, wherein the shielding layer is arranged on a top surface or a bottom surface of the controller and is used for shielding electromagnetic interference of a magnetic element.

27. The power supply module of claim 1, wherein the power block comprises at least two output positive terminals Vout and at least two output negative terminals GND;
the output positive terminal Vout and the output negative terminal GND are evenly distributed in a contour of at least two thirds of the projection surface of the power block on the large-area pin board.

28. The power supply module of claim 27, wherein the two output negative terminals GND are distributed near two opposite sides of the power block; the output positive terminals Vout are distributed in a relatively intermediate aliquot position.

29. The power supply module of claim 27, wherein the output negative terminal GND and the output positive terminal Vout are balanced and staggered relative to each other.

30. The power supply module of claim 27, wherein each power block comprises at least four power units;
the output positive terminal Vout of each power unit is connected in parallel on the large-area pin board;
an output capacitor is disposed in the blank area between the output positive terminal Vout and the output negative terminal GND pin.

31. The power supply module of claim 30, wherein at least four power units operate at the same frequency, and have an equalization staggered phase and a total phase of 360 degrees.

32. The power supply module of claim 13, wherein the magnetic element includes an inductive winding; the inductive winding penetrates from above the magnetic element in a single turn and in a straight line manner.

33. The power supply module of claim 1, wherein a plurality of test points are further arranged on the first side surface or the third side surface of the control module, and the test points are arranged in an array.

34. The power supply module of claim 20, wherein an input power electrodes Vin and GND of the input terminal are disposed on a top electroplated layer of the power block.

35. A vertical power delivery system, comprising:
comprising a computing power chip, a system PCB, and the power supply module of claim 1;
the computing power chip and the power supply module are respectively arranged on two sides of the system PCB;
the computing power chip, the system PCB, and the power supply module are electrically connected.

36. The vertical power delivery system of claim 35, wherein the large-area pin board is integrated on the surface layer of the system PCB.
